(19) United States
(12) Patent Application Publication
(10) Pub. No.: US 2024/0163053 A1
(43) Pub. Date: May 16, 2024

(54) SRS Data Transmission

(71) Applicants: NOKIA SHANGHAI BELL CO.,LTD., Shanghai (CN); NOKIA SOLUTIONS AND NETWORKS OY, Espoo (FI)

(72) Inventors: Hao LIU, Shanghai (CN); Baocai LI, Zhejiang (CN); Dan SHI, Zhejiang (CN); Tao YANG, Shanghai (CN); Nuan SONG, Shanghai (CN); Yan ZHAO, Shanghai (CN)

(21) Appl. No.: 18/280,709

(22) PCT Filed: Mar. 11, 2021
(86) PCT No.: PCT/CN2021/080245

§ 371 Date: Sep. 7, 2023

(51) Int. Cl. H04L 5/00; H04L 25/02; H04W 28/06

(52) U.S. Cl. CPC H04L 5/0051; H04L 25/0226; H04W 28/06

(57) ABSTRACT

Embodiments of the present disclosure relate to methods, apparatuses and computer readable storage media for SRS data transmission. In example embodiments, a method is provided. According to the method, an apparatus forwards, during a first period, first SRS data received from a terminal device to a further apparatus. The further apparatus determines, based on the first SRS data, compression information for compressing SRS data, and transmits the compression information to the apparatus. Thereby, the apparatus compresses, during a second period, second SRS data received from the terminal device based on the compression information, and transmits, during the second period, the compressed second SRS data to the further apparatus. In this way, the SRS data can be effectively compressed, thus reducing the latency of the SRS data transmission.

### TECHNICAL FIELD

Embodiments of the present disclosure generally relate to the field of telecommunication, and in particular, to methods, apparatuses and computer readable storage media for sounding reference signal (SRS) data transmission.

### BACKGROUND

Eigenmode Based Beamforming (EBB) solution exploiting Time Division Duplex (TDD) uplink/downlink channel reciprocity can provide better beamforming gain and potential performance gain compared with the existing Grid-of-Beam (GoB) solution. In this case, the TDD EBB solution becomes a candidate beamforming feature for TDD 5th-Generation (5G) product design. Thus, the performance of the TDD EBB solution needs to be improved.

### SUMMARY

In general, example embodiments of the present disclosure provide methods, apparatuses and computer readable storage media for SRS data transmission.

In a first aspect, there is provided an apparatus. The apparatus comprises at least one processor; and at least one memory including computer program codes; the at least one memory and the computer program codes are configured to, with the at least one processor, cause the apparatus to forward, during a first period, first SRS data received from a terminal device to a further apparatus; receive, from the further apparatus, compression information for compressing SRS data, the compression information being determined based on the first SRS data; compress, during a second period, second SRS data received from the terminal device based on the compression information; and transmit, during the second period, the compressed second SRS data to the further apparatus.

In a second aspect, there is provided an apparatus. The apparatus comprises at least one processor; and at least one memory including computer program codes; the at least one memory and the computer program codes are configured to, with the at least one processor, cause the apparatus to receive, during a first period, first SRS data from a further apparatus; determine, based on the first SRS data, compression information for compressing SRS data; transmit the compression information to the further apparatus; and receive, during a second period, second SRS data compressed based on the compression information from the further apparatus.

In a third aspect, there is provided a method. The method comprises forwarding, at an apparatus and during a first period, first SRS data received from a terminal device to a further apparatus; receiving, from the further apparatus, compression information for compressing SRS data, the compression information being determined based on the first SRS data; compressing, during a second period, second SRS data received from the terminal device based on the compression information; and transmitting, during the second period, the compressed second SRS data to the further apparatus.

In a fourth aspect, there is provided a method. The method comprises receiving, at an apparatus and during a first period, first SRS data from a further apparatus; determining, based on the first SRS data, compression information for compressing SRS data; transmitting the compression information to the further apparatus; and receiving, during a second period, second SRS data compressed based on the compression information from the further apparatus.

In a fifth aspect, there is provided an apparatus. The apparatus comprises means for forwarding, during a first period, first SRS data received from a terminal device to a further apparatus; means for receiving, from the further apparatus, compression information for compressing SRS data, the compression information being determined based on the first SRS data; means for compressing, during a second period, second SRS data received from the terminal device based on the compression information; and means for transmitting, during the second period, the compressed second SRS data to the further apparatus.

In a sixth aspect, there is provided an apparatus. The apparatus comprises means for receiving, during a first period, first SRS data from a further apparatus; means for determining, based on the first SRS data, compression information for compressing SRS data; means for transmitting the compression information to the further apparatus; and means for receiving, during a second period, second SRS data compressed based on the compression information from the further apparatus.

In a seventh aspect, there is a computer readable storage medium comprising program instructions stored thereon. The instructions, when executed by an apparatus, cause the apparatus to perform the method according to the above third or fourth aspect.

In an eighth aspect, there is provided a computer program product that is stored on a computer readable medium and includes machine-executable instructions. The machine-executable instructions, when being executed, cause a machine to perform the method according to the above third or fourth aspect.

It is to be understood that the summary section is not intended to identify key or essential features of embodiments of the present disclosure, nor is it intended to be used to limit the scope of the present disclosure. Other features of the present disclosure will become easily comprehensible through the following description.

### BRIEF DESCRIPTION OF THE DRAWINGS

Through the more detailed description of some example embodiments of the present disclosure in the accompanying drawings, the above and other objects, features and advantages of the present disclosure will become more apparent, wherein:

FIG. 1 illustrates a block diagram of example environments in which embodiments of the present disclosure can be implemented;

FIG. 2 illustrates a signaling chart of an example process for communication according to some example embodiments of the present disclosure;

FIG. 3 illustrates a schematic diagram of an example of raw SRS data in accordance with some example embodiments of the present disclosure;

FIG. 4 illustrates a schematic diagram of an example of SRS data transmission periods in accordance with some example embodiments of the present disclosure;

FIG. 5 illustrates a schematic diagram of an example of SRS data compression in accordance with some example embodiments of the present disclosure;

FIG. 6 illustrates a flowchart of an example method according to some example embodiments of the present disclosure;

FIG. 7 illustrates a flowchart of an example method according to some example embodiments of the present disclosure;

FIG. 8 illustrates a simplified block diagram of an apparatus that is suitable for implementing embodiments of the present disclosure; and

FIG. 9 illustrates a block diagram of an example computer readable medium in accordance with some example embodiments of the present disclosure.

Throughout the drawings, the same or similar reference numerals represent the same or similar element.

### DETAILED DESCRIPTION

Principle of the present disclosure will now be described with reference to some example embodiments. It is to be understood that these embodiments are described only for the purpose of illustration and help those skilled in the art to understand and implement the present disclosure, without suggesting any limitation as to the scope of the disclosure. The disclosure described herein can be implemented in various manners other than the ones described below.

In the following description and claims, unless defined otherwise, all technical and scientific terms used herein have the same meaning as commonly understood by one of ordinary skills in the art to which this disclosure belongs.

References in the present disclosure to “one embodiment,” “an embodiment,” “an example embodiment,” and the like indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an example embodiment, it is submitted that it is within the knowledge of one skilled in the art to affect such feature, structure, or characteristic in connection with other embodiments whether or not explicitly described.

It shall be understood that although the terms “first” and “second” etc. may be used herein to describe various elements, these elements should not be limited by these terms. These terms are only used to distinguish one element from another. For example, a first element could be termed a second element, and similarly, a second element could be termed a first element, without departing from the scope of example embodiments. As used herein, the term “and/or” includes any and all combinations of one or more of the listed terms.

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components etc., but do not preclude the presence or addition of one or more other features, elements, components and/or combinations thereof.

As used in this application, the term “circuitry” may refer to one or more or all of the following:
(a) hardware-only circuit implementations (such as implementations in only analog and/or digital circuitry) and
(b) combinations of hardware circuits and software, such as (as applicable):
   (i) a combination of analog and/or digital hardware circuit(s) with software/firmware and
   (ii) any portions of hardware processor(s) with software (including digital signal processor(s)), software, and memory(ies) that work together to cause an apparatus, such as a mobile phone or server, to perform various functions) and
(c) hardware circuit(s) and or processor(s), such as a microprocessor(s) or a portion of a microprocessor(s), that requires software (e.g., firmware) for operation, but the software may not be present when it is not needed for operation.

This definition of circuitry applies to all uses of this term in this application, including in any claims. As a further example, as used in this application, the term circuitry also covers an implementation of merely a hardware circuit or processor (or multiple processors) or portion of a hardware circuit or processor and its (or their) accompanying software and/or firmware. The term circuitry also covers, for example and if applicable to the particular claim element, a baseband integrated circuit or processor integrated circuit for a mobile device or a similar integrated circuit in server, a cellular network device, or other computing or network device.

As used herein, the term “communication network” refers to a network following any suitable communication standards, such as Long Term Evolution (LTE), LTE-Advanced (LTE-A), Wideband Code Division Multiple Access (WCDMA), High-Speed Packet Access (HSPA), Narrow Band Internet of Things (NB-IoT), New Radio (NR) and so on. Furthermore, the communications between a terminal device and a network device in the communication network may be performed according to any suitable generation communication protocols, including, but not limited to, the first generation (1G), the second generation (2G), 2.5G, 2.75G, the third generation (3G), the fourth generation (4G), 4.5G, the future fifth generation (5G) communication protocols, and/or any other protocols either currently known or to be developed in the future. Embodiments of the present disclosure may be applied in various communication systems. Given the rapid development in communications, there will of course also be future type communication technologies and systems with which the present disclosure may be embodied. It should not be seen as limiting the scope of the present disclosure to only the aforementioned system.

As briefly discussed above, the TDD EBB solution becomes a candidate beamforming feature for TDD 5th-Generation (5G) product design. Traditionally, in the TDD EBB solution, SRS data is received from all transceivers (TRX) in a radio frequency unit (RFU). The raw SRS data may be pre-combined in the RFU with a predefined beamformer to reduce its data rate. Alternatively, the raw SRS data may not be processed in the RFU. In either way, the pre-combined SRS data or raw SRS data may be forwarded to a Baseband Unit (BBU) via at least one fronthaul link. The BBU performs channel estimation according to the received SRS data and determines proper eigenvectors used for EBB operation and data transmission.

Fronthaul link capability may affect EBB implementation. For example, if a Delay Managed (DM) Common Public Radio Interface (CPRI) link is used for SRS data transmission, the raw SRS data needs to be pre-combined in the RFU to reduce its data rate due to the limited fronthaul bandwidth of the DM CPRI link, and transmitted to the BBU for further processing. If a Non-Delay Managed (NDM) Evolved Common Public Radio Interface (eCPRI) link is used for SRS data transmission, the raw SRS data can be directly delivered to the BBU without pre-combination due to the sufficient fronthaul bandwidth for the NDM eCPRI link, and transmitted in several symbols with the time multiplexed mode. In the latter case, large amount of raw SRS data may come from multiple TRX ports of the RFU (in spatial domain) and multiple SRS subcarriers or physical resource blocks (PRBs) (in frequency dimension). As such, if the raw SRS data can be compressed in the RFU exploiting spatial or frequency correlation, the transmission latency from the RFU to the BBU can be significantly reduced.

Embodiments of the present disclosure provide a solution for SRS data transmission, so as to solve the above problems and one or more of other potential problems. According to this solution, dual-periodic configuration can be used for SRS data transmission. That is to say, two SRS data transmission periods can be used to effectively convey raw SRS data or compressed SRS data from a radio frequency unit to a baseband unit via a fronthaul link.

Specifically, the raw SRS data can be transmitted from the radio frequency unit to the baseband unit without compression during a configured long period. The baseband unit can determine compression information for compressing SRS data based on the received raw SRS data. For example, the compression information may include spatial and/or frequency domain compression information, such as, the indices of spatial GoB beams and/or the indices of frequency components (or taps). The baseband unit can inform the radio frequency unit of the compression information via the fronthaul link during the long period.

Thereby, the radio frequency unit can further compress raw SRS data based on the received compression information, and transmit the compressed SRS data to the baseband unit during a configured short period. In this way, the SRS data can be effectively compressed, without requiring extra implementation complexity of the radio frequency unit for determining the compression information. Thus, the SRS data exchange latency can be reduced.

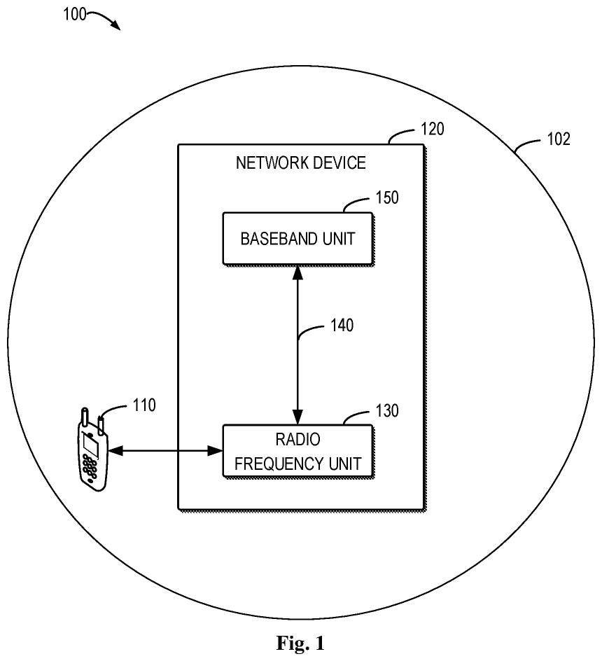

Reference is now made to FIG. 1, which illustrates a block diagram of example environments in which embodiments of the present disclosure can be implemented.

FIG. 1 shows an example communication network 100 in which example embodiments of the present disclosure can be implemented. The communication network 100 includes a terminal device 110 and a network device 120 serving the terminal device 110. The terminal device 110 and the network device 120 can communicate with each other. The serving area of the network device 120 is called as a cell 102. It is to be understood that the number of terminal devices, network devices and cells is only for the purpose of illustration without suggesting any limitations. The communication network 100 may include any suitable number of terminal devices, network devices and cells adapted for implementing embodiments of the present disclosure. Furthermore, the functionalities of the network device can be split into multiple network nodes, such as Transmission and Reception Points (TRPs), centralized unit (CU) and DU, etc. Although not shown, it would be appreciated that a plurality of terminal devices may be located in the cell 102 and served by the network device 120.

Communications in the communication network 100 may be implemented according to any proper communication protocol(s), comprising, but not limited to, cellular communication protocols of the first generation (1G), the second generation (2G), the third generation (3G), the fourth generation (4G) and the fifth generation (5G) and on the like, wireless local network communication protocols such as Institute for Electrical and Electronics Engineers (IEEE) 802.11 and the like, and/or any other protocols currently known or to be developed in the future. Moreover, the communication may utilize any proper wireless communication technology, comprising but not limited to: Code Divided Multiple Address (CDMA), Frequency Divided Multiple Address (FDMA), Time Divided Multiple Address (TDMA), Frequency Divided Duplexer (FDD), Time Divided Duplexer (TDD), Multiple-Input Multiple-Output (MIMO), Orthogonal Frequency Divided Multiple Access (OFDMA) and/or any other technologies currently known or to be developed in the future.

In the network 100, the terminal device 110 and the network device 120 can communicate data and control information to each other. A link from the network device 120 to the terminal device 110 is referred to as a downlink (DL), while a link from the terminal device 110 to the network device 120 is referred to as an uplink (UL).

Specifically, the terminal device 110 can transmit SRS data to the network device 120. The network device 120 includes a radio frequency unit 130 and a baseband unit 150. The radio frequency unit 130 can receive the SRS data and forward the raw/compressed SRS data to the baseband unit 150. The baseband unit 150 can transmit compression information for compressing SRS data to the radio frequency unit 130. In some example embodiments, the radio frequency unit 130 and the baseband unit 150 can communicate via at least one fronthaul link 140 between the radio frequency unit 130 and the baseband unit 150. For example, the fronthaul can support a DM CPRI link, a NDM eCPRI link, or the like.

It is to be understood that the network environments 100 and/or 105 are shown only for purpose of illustration, without suggesting any limitations as to the scope of the present disclosure. Embodiments of the present disclosure may also be applied to an environment with a different structure.

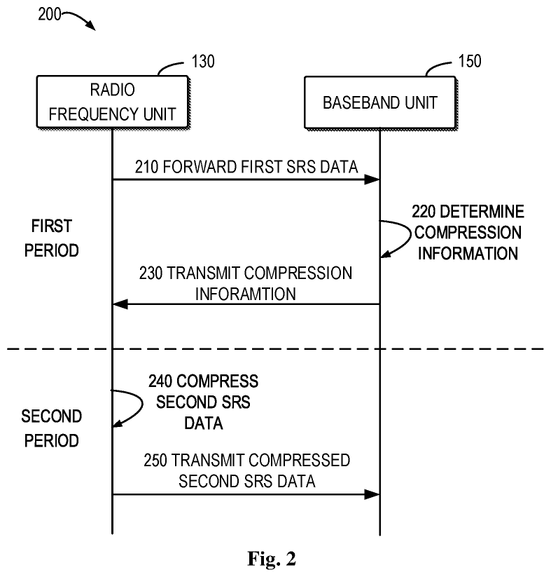

Regarding the network environment 100 as shown in FIG. 1, FIG. 2 illustrates a signaling chart of an example process 200 according to some example embodiments of the present disclosure. As shown in FIG. 2, the process 200 involves the radio frequency unit 130 and the baseband unit 150 as shown in FIG. 1.

As shown in FIG. 2, the radio frequency unit 130 may forward 210, during a first period, first SRS data received from the terminal device 110 to the baseband unit 150. In some example embodiments, the radio frequency unit 130 may forward, via at least one fronthaul link 140 between the radio frequency unit 130 and the baseband unit 150, the first SRS data from the radio frequency unit to the baseband unit 150 during the first period.

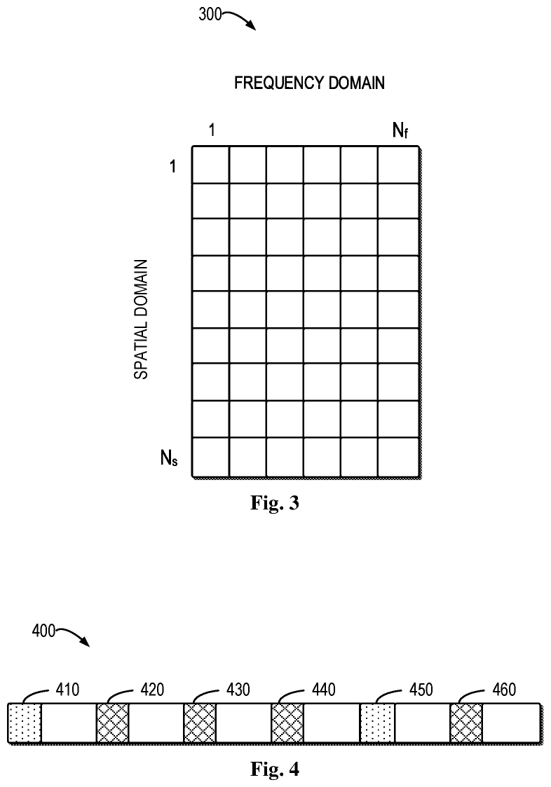

An example of the first SRS data is shown in FIG. 3, which illustrates a schematic diagram of an example of raw SRS data 300 in accordance with some example embodiments of the present disclosure. The number of TRX ports of the radio frequency unit 130 can be set to Nₛ, and the number of frequency units (such as, subcarriers or PRBs) can be set to N_{f}, in which Nₛ and N_{f} are both positive integers larger than or equal to 1. In this case, as shown in FIG. 3, the first SRS data 300 is of the dimension of Nₛ×N_{f} assuming that the terminal device 110 has one antenna port for SRS data transmission. It is to be understood that, if the terminal device 110 has more than one antenna port for SRS data transmission, the dimension or the quantity of the first SRS data may be proportional to the number of antenna ports of the terminal device 110.

In addition, an example of the first period is shown in FIG. 4, which illustrates a schematic diagram of an example of SRS data transmission periods 400 in accordance with some example embodiments of the present disclosure. As shown in FIG. 4, the first period may be the period 410 or 450. Particularly, the first period can be configured as a relatively long period. In some example embodiments, the configuration of the first period (for example, a time interval between the periods 410 and 450) may consider the impact of a moving speed of the terminal device. If the moving speed of the terminal device is low, the time interval between the periods 410 and 450 may be configured to be large enough due to slow variation of channel characteristic, including spatial or frequency compression beams. Otherwise, the time interval between the periods 410 and 450 may be shortened to ensure the satisfactory channel reconstruction accuracy in the baseband unit.

Returning back to FIG. 2, in some example embodiments, the first SRS data is not compressed and can be treated as raw SRS data. Alternatively, before transmitting the first SRS data, the radio frequency unit 130 may pre-combine the first SRS data with predefined beamforming weights in the spatial domain. The pre-combination may reduce the SRS data transmission appropriately, but may lead to some feature loss of uplink SRS channel in the spatial domain, so that spatial domain compression information cannot be determined by the baseband unit 150 according to the pre-combined SRS data.

The baseband unit 150 may receive, during the first period, the first SRS data from the radio frequency unit 130. In some example embodiments, the baseband unit 150 may receive, via at least one fronthaul link 140 between the radio frequency unit 130 and the baseband unit 150, the first SRS data from the radio frequency unit 130 during the first period.

The baseband unit 150 may determine 220, based on the first SRS data, compression information for compressing SRS data. In some example embodiments, the compression information may include spatial and/or frequency domain compression information, such as spatial GoB beams and/or frequency components (or taps).

For example, in spatial domain of raw SRS data, L orthogonal GoB beams may be selected from predefined Discrete Fourier Transform (DFT) vectors for a polarization direction, and used to compress Nₛ TRX ports to 2L beam ports exploiting spatial correlation of the uplink SRS channel. Alternatively or in addition, in some example embodiments, in frequency domain of raw SRS data, M frequency components (or taps) may be selected from other predefined DFT vectors, and used to compress N_{f} frequency units to M frequency components exploiting frequency correlation of the uplink SRS channel. L and M are both positive integers smaller than Nₛ and N_{f}, respectively. In this case, the compression information may be the selected indices of the spatial GoB beams and/or frequency components. It is to be understood that, the complete set of DFT vectors may be pre-configured at the baseband unit 150 for the spatial and/or frequency domain, and the baseband unit 150 may inform the radio frequency unit 130 of the two sets of DFT vectors and the corresponding mapping relation between the indices and DFT vectors for each set, via the at least one fronthaul link 140. Since the two sets of DFT vectors may be configured statically, the baseband unit 150 may exchange them with the radio frequency unit 130 only once.

Then, the baseband unit 150 may transmit 230 the compression information to the radio frequency unit 130. In some example embodiments, the baseband unit 150 may transmit, via the at least one fronthaul link 140, the compression information from the baseband unit 150 to the radio frequency unit 130. In some example embodiments, the baseband unit 150 may also store the compression information, such that the stored compression information can be used for future SRS data decompression in the baseband unit 150.

The radio frequency unit 130 may receive, from the baseband unit 150, the compression information. In some example embodiments, the radio frequency unit 130 may receive, via the at least one fronthaul link 140, the compression information from the baseband unit 150.

The compression information may remain unchanged for a certain duration and can be stored at the radio frequency unit 130 for future SRS data compression. In this case, the radio frequency unit 130 may compress 240, during a second period, second SRS data received from the terminal device 110 based on the compression information.

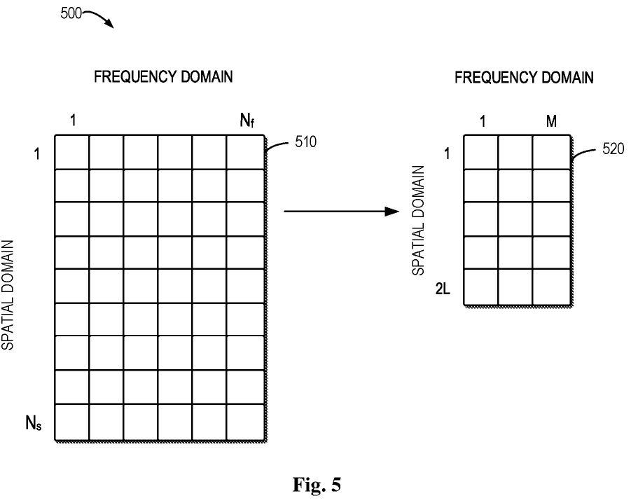

Similar to the first SRS data, the second SRS data may be raw SRS data. An example of the second SRS data is shown in FIG. 5, which illustrates a schematic diagram of an example of SRS data compression 500 in accordance with some example embodiments of the present disclosure. As shown in FIG. 5, the number of TRX ports of the radio frequency unit 130 can be set to Nₛ, and the number of frequency units (such as, subcarriers or PRBs) can be set to N_{f}. In this case, the second SRS data 510 is of the dimension of Nₛ×N_{f} assuming that the terminal device has one antenna port for SRS data transmission. It is to be understood that, if the terminal device 110 has more than one antenna port for SRS data transmission, the dimension or the quantity of the first SRS data may be proportional to the number of antenna ports of the terminal device 110. Although the second SRS data 510 is shown to have the same dimensions as the first SRS data 300, the second SRS data may usually be different from the first SRS data due to different transmission instances.

In addition, an example of the second period is shown in FIG. 4. As shown, the second period may be the period 420, 430, 440 or 460. Particularly, the second period can be configured as a relatively short period. For example, as shown in FIG. 4, a time interval between the periods 420 and 430 may be configured to be shorter than the time interval between the periods 410 and 450.

In some example embodiments, if the compression information comprises spatial domain compression information, the radio frequency unit 130 may compress spatial dimensions of the second SRS data based on the spatial domain compression information. Alternatively or in addition, if the compression information comprises frequency domain compression information, the radio frequency unit 130 may compress frequency units of the second SRS data based on the frequency domain compression information.

For example, as shown in FIG. 5, it is assumed that the compress information indicates L spatial GoB beams for a polarization direction and M frequency components. During the second period, the radio frequency unit 130 may receive the second SRS data and multiply Nₛ TRX ports of the second SRS data with L spatial GoB beams in both polarizations, respectively. In this way, the spatial dimension of the second SRS data can be compressed from Nₛ TRX ports to 2L beam ports. Alternatively or in addition, the radio frequency unit 130 may multiply N_{f} frequency units of the second SRS data with M frequency components, respectively. In this way, the frequency dimension of the second SRS data can be compressed from N_{f} frequency units to M frequency components.

As a result, as shown by the compressed second SRS data 520 in FIG. 5, the number of the second SRS data is compressed at the radio frequency unit 130 to 2L×M, which is far less than the original value Nₛ×N_{f}.

The radio frequency unit 130 transmits 250, during the second period, the compressed second SRS data to the baseband unit 150. In some example embodiments, the radio frequency unit 130 may transmit, via the at least one fronthaul link 140, the compressed second SRS data from the radio frequency unit 130 to the baseband unit 150 during the second period.

As such, the efficient SRS compression may result in low transmission latency from the radio frequency unit 130 to the baseband unit 150, while the radio frequency unit 130 does not demand extra implementation complexity for determining the compression information.

The baseband unit 150 may receive, during the second period, the second SRS data compressed based on the compression information from the radio frequency unit 130. In some example embodiments, the baseband unit 150 may receive, via the at least one fronthaul link 140, the second SRS data from the radio frequency unit 130 during the second period. In some example embodiments, if the compression information comprises spatial domain compression information, spatial dimensions of the second SRS data are compressed based on the spatial domain compression information. Alternatively or in addition, if the compression information comprises frequency domain compression information, frequency units of the second SRS data are compressed based on the frequency domain compression information.

Further, in some example embodiments, the baseband unit 150 may decompress the second SRS data based on the compression information, and may perform a channel estimation based on the decompressed second SRS data. As such, the second SRS data can be effectively reconstructed in the baseband unit 150 leveraging the stored compression information with satisfactory channel accuracy.

In addition, as discussed above, the compression information may remain unchanged for a certain duration. In this case, when the duration expires, the radio frequency unit 130 may forward, during a next long period, raw SRS data received from the terminal device 110 to the baseband unit 150. The baseband unit 150 may update the compression information based on raw SRS data. In this way, the compression information can be dynamically adjusted with the changing channel condition.

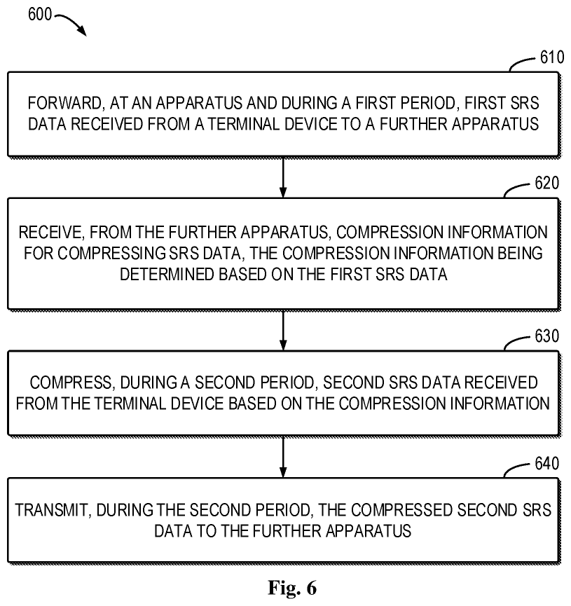

FIG. 6 illustrates a flowchart of an example method 600 according to some example embodiments of the present disclosure. The method 600 can be implemented at an apparatus, such as, the radio frequency unit 130 as shown in FIG. 1. It is to be understood that the method 600 may include additional blocks not shown and/or may omit some shown blocks, and the scope of the present disclosure is not limited in this regard. In the following, the radio frequency unit 130 also referred to as “apparatus”.

At block 610, the apparatus (such as the radio frequency unit 130) forwards, during a first period, first SRS data received from a terminal device 110 to a further apparatus (such as the baseband unit 150).

At block 620, the apparatus receives, from the further apparatus, compression information for compressing SRS data, the compression information being determined based on the first SRS data.

At block 630, the apparatus compresses, during a second period, second SRS data received from the terminal device based on the compression information.

At block 640, the apparatus transmits, during the second period, the compressed second SRS data to the further apparatus.

In some example embodiments, in accordance with a determination that the compression information comprises spatial domain compression information, the apparatus may compress spatial dimensions of the second SRS data based on the spatial domain compression information. In accordance with a determination that the compression information comprises frequency domain compression information, the apparatus may compress frequency units of the second SRS data based on the frequency domain compression information.

In some example embodiments, the apparatus may be a radio frequency unit of a network device (such as the network device 120) and the further apparatus may be a baseband unit of the network device.

In some example embodiments, the apparatus may forward, via at least one fronthaul link (such as the fronthaul link 140) between the radio frequency unit and the baseband unit, the first SRS data from the radio frequency unit to the baseband unit during the first period. The apparatus may receive, via the at least one fronthaul link, the compression information from the baseband unit. The apparatus may transmit, via the at least one fronthaul link, the compressed second SRS data from the radio frequency unit to the baseband unit during the second period.

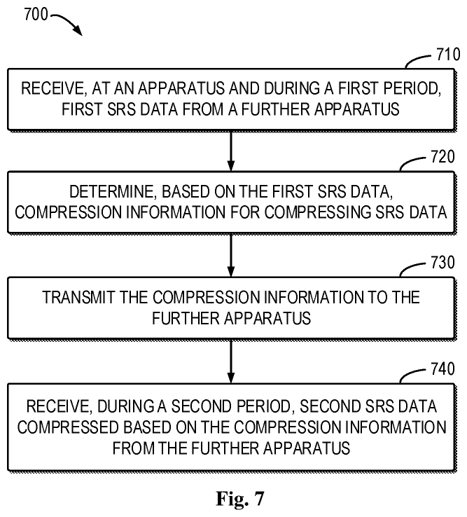

FIG. 7 illustrates a flowchart of an example method 700 according to some example embodiments of the present disclosure. The method 700 can be implemented at an apparatus, such as, the baseband unit 150 as shown in FIG. 1. It is to be understood that the method 700 may include additional blocks not shown and/or may omit some shown blocks, and the scope of the present disclosure is not limited in this regard. In the following, the baseband unit 150 also referred to as “apparatus”.

At block 710, the apparatus (such as, the baseband unit 150) receives, during a first period, first SRS data from a further apparatus (such as the radio frequency unit 130).

At block 720, the apparatus determines, based on the first SRS data, compression information for compressing SRS data.

At block 730, the apparatus transmits the compression information to the further apparatus.

At block 740, the apparatus receives, during a second period, second SRS data compressed based on the compression information from the further apparatus.

In some example embodiments, the apparatus may perform a channel estimation based on the first SRS data.

In some example embodiments, the apparatus may decompress the received second SRS data based on the compression information. The apparatus may perform a channel estimation based on the decompressed second SRS data.

In some example embodiments, the compression information may comprise spatial domain compression information. The apparatus may receive the second SRS data from the further apparatus during the second period. Spatial dimensions of the second SRS data may be compressed based on the spatial domain compression information.

In some example embodiments, the compression information may comprise frequency domain compression information. The apparatus may receive the second SRS data from the further apparatus during the second period. Frequency units of the second SRS data may be compressed based on the frequency domain compression information.

In some example embodiments, the apparatus may be a baseband unit of a network device (such as the network device 120) and the further apparatus may be a radio frequency unit of the network device.

In some example embodiments, the apparatus may receive, via at least one fronthaul link (such the fronthaul link 140) between the radio frequency unit and the baseband unit, the first SRS data from the radio frequency unit during the first period. The apparatus may transmit, via the at least one fronthaul link, the compression information from the baseband unit to the radio frequency unit. The apparatus may receive, via the at least one fronthaul link, the second SRS data from the radio frequency unit during the second period.

In some example embodiments, an apparatus capable of performing the method 600 may comprise means for performing the respective steps of the method 600. The means may be implemented in any suitable form. For example, the means may be implemented in a circuitry or software module.

In some example embodiments, the apparatus capable of performing the method 600 comprises: means for forwarding, during a first period, first SRS data received from a terminal device to a further apparatus; means for receiving, from the further apparatus, compression information for compressing SRS data, the compression information being determined based on the first SRS data; means for compressing, during a second period, second SRS data received from the terminal device based on the compression information; and means for transmitting, during the second period, the compressed second SRS data to the further apparatus.

In some example embodiments, the means for compressing the second SRS data may comprise: means for, in accordance with a determination that the compression information comprises spatial domain compression information, compressing spatial dimensions of the second SRS data based on the spatial domain compression information; and means for, in accordance with a determination that the compression information comprises frequency domain compression information, compressing frequency units of the second SRS data based on the frequency domain compression information.

In some example embodiments, the apparatus may be a radio frequency unit of a network device and the further apparatus may be a baseband unit of the network device.

In some example embodiments, the means for forwarding the first SRS data may comprise: mean for forwarding, via at least one fronthaul link between the radio frequency unit and the baseband unit, the first SRS data from the radio frequency unit to the baseband unit during the first period. The means for receiving the compression information may comprise: means for receiving, via the at least one fronthaul link, the compression information from the baseband unit. The means for transmitting the compressed second SRS data may comprise: means for transmitting, via the at least one fronthaul link, the compressed second SRS data from the radio frequency unit to the baseband unit during the second period.

In some example embodiments, an apparatus capable of performing the method 700 may comprise means for performing the respective steps of the method 700. The means may be implemented in any suitable form. For example, the means may be implemented in a circuitry or software module.

In some example embodiments, the apparatus capable of performing the method 700 comprises: means for receiving, during a first period, first SRS data from a further apparatus; means for determining, based on the first SRS data, compression information for compressing SRS data; means for transmitting the compression information to the further apparatus; and means for receiving, during a second period, second SRS data compressed based on the compression information from the further apparatus.

In some example embodiments, the apparatus capable of performing the method 700 may further comprise: means for performing a channel estimation based on the first SRS data.

In some example embodiments, the apparatus capable of performing the method 700 may further comprise: means for decompressing the received second SRS data based on the compression information; and means for performing a channel estimation based on the decompressed second SRS data.

In some example embodiments, the compression information may comprise spatial domain compression information, and the means for receiving the second SRS data may comprise: means for receiving the second SRS data from the further apparatus during the second period, spatial dimensions of the second SRS data being compressed based on the spatial domain compression information.

In some example embodiments, the compression information may comprise frequency domain compression information, and the means for receiving the second SRS data may comprise: means for receiving the second SRS data from the further apparatus during the second period, frequency units of the second SRS data being compressed based on the frequency domain compression information.

In some example embodiments, the apparatus may be a baseband unit of a network device and the further apparatus may be a radio frequency unit of the network device.

In some example embodiments, the means for receiving the first SRS data may comprise: means for receiving, via at least one fronthaul link between the radio frequency unit and the baseband unit, the first SRS data from the radio frequency unit during the first period. The means for transmitting the compression information to the further apparatus may comprise: means for transmitting, via the at least one fronthaul link, the compression information from the baseband unit to the radio frequency unit. The means for receiving the second SRS data may comprise: means for receiving, via the at least one fronthaul link, the second SRS data from the radio frequency unit during the second period.

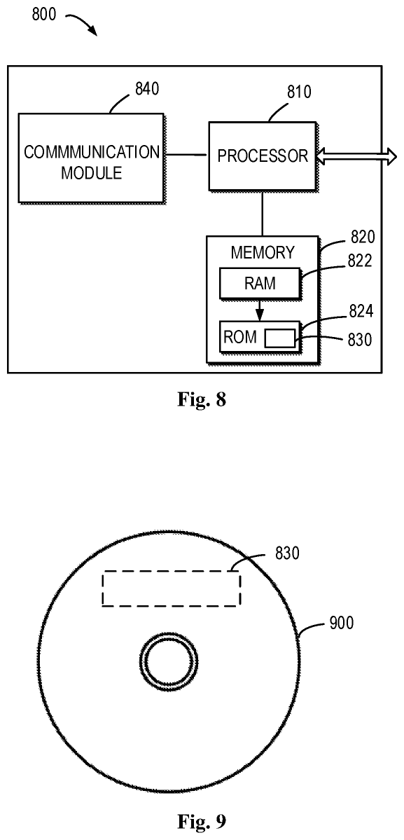

FIG. 8 is a simplified block diagram of a device 800 that is suitable for implementing embodiments of the present disclosure. For example, the radio frequency unit 130 and/or the baseband unit 150 can be implemented by the device 800. As shown, the device 800 includes one or more processors 810, one or more memories 820 coupled to the processor 810, and one or more communication modules 840 coupled to the processor 810.

The communication module 840 is for bidirectional communications. The communication module 840 has at least one antenna to facilitate communication. The communication interface may represent any interface that is necessary for communication with other network elements.

The processor 810 may be of any type suitable to the local technical network and may include one or more of the following: general purpose computers, special purpose computers, microprocessors, digital signal processors (DSPs) and processors based on multicore processor architecture, as non-limiting examples. The device 800 may have multiple processors, such as an application specific integrated circuit chip that is slaved in time to a clock which synchronizes the main processor.

The memory 820 may include one or more non-volatile memories and one or more volatile memories. Examples of the non-volatile memories include, but are not limited to, a Read Only Memory (ROM) 824, an electrically programmable read only memory (EPROM), a flash memory, a hard disk, a compact disc (CD), a digital video disk (DVD), and other magnetic storage and/or optical storage. Examples of the volatile memories include, but are not limited to, a random access memory (RAM) 822 and other volatile memories that will not last in the power-down duration.

A computer program 830 includes computer executable instructions that are executed by the associated processor 810. The program 830 may be stored in the ROM 824. The processor 810 may perform any suitable actions and processing by loading the program 830 into the RAM 822.

The embodiments of the present disclosure may be implemented by means of the program 830 so that the device 800 may perform any process of the disclosure as discussed with reference to FIG. 2. The embodiments of the present disclosure may also be implemented by hardware or by a combination of software and hardware.

In some example embodiments, the program 830 may be tangibly contained in a computer readable medium which may be included in the device 800 (such as in the memory 820) or other storage devices that are accessible by the device 800. The device 800 may load the program 830 from the computer readable medium to the RAM 822 for execution. The computer readable medium may include any types of tangible non-volatile storage, such as ROM, EPROM, a flash memory, a hard disk, CD, DVD, and the like. FIG. 9 shows an example of the computer readable medium 900 in form of CD or DVD. The computer readable medium has the program 830 stored thereon.

It should be appreciated that future networks may utilize network functions virtualization (NFV) which is a network architecture concept that proposes virtualizing network node functions into “building blocks” or entities that may be operationally connected or linked together to provide services. A virtualized network function (VNF) may comprise one or more virtual machines running computer program codes using standard or general type servers instead of customized hardware. Cloud computing or data storage may also be utilized. In radio communications, this may mean node operations to be carried out, at least partly, in a central/centralized unit, CU, (e.g. server, host or node) operationally coupled to distributed unit, DU, (e.g. a radio head/node). It is also possible that node operations will be distributed among a plurality of servers, nodes or hosts. It should also be understood that the distribution of labour between core network operations and base station operations may vary depending on implementation.

In an embodiment, the server may generate a virtual network through which the server communicates with the distributed unit. In general, virtual networking may involve a process of combining hardware and software network resources and network functionality into a single, software-based administrative entity, a virtual network. Such virtual network may provide flexible distribution of operations between the server and the radio head/node. In practice, any digital signal processing task may be performed in either the CU or the DU and the boundary where the responsibility is shifted between the CU and the DU may be selected according to implementation.

Therefore, in an embodiment, a CU-DU architecture is implemented. In such case the apparatus 800 may be comprised in a central unit (e.g. a control unit, an edge cloud server, a server) operatively coupled (e.g. via a wireless or wired network) to a distributed unit (e.g. a remote radio head/node). That is, the central unit (e.g. an edge cloud server) and the distributed unit may be stand-alone apparatuses communicating with each other via a radio path or via a wired connection. Alternatively, they may be in a same entity communicating via a wired connection, etc. The edge cloud or edge cloud server may serve a plurality of distributed units or a radio access networks. In an embodiment, at least some of the described processes may be performed by the central unit. In another embodiment, the apparatus 800 may be instead comprised in the distributed unit, and at least some of the described processes may be performed by the distributed unit.

In an embodiment, the execution of at least some of the functionalities of the apparatus 800 may be shared between two physically separate devices (DU and CU) forming one operational entity. Therefore, the apparatus may be seen to depict the operational entity comprising one or more physically separate devices for executing at least some of the described processes. In an embodiment, such CU-DU architecture may provide flexible distribution of operations between the CU and the DU. In practice, any digital signal processing task may be performed in either the CU or the DU and the boundary where the responsibility is shifted between the CU and the DU may be selected according to implementation. In an embodiment, the apparatus 800 controls the execution of the processes, regardless of the location of the apparatus and regardless of where the processes/functions are carried out.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device. While various aspects of embodiments of the present disclosure are illustrated and described as block diagrams, flowcharts, or using some other pictorial representations, it is to be understood that the block, apparatus, system, technique or method described herein may be implemented in, as non-limiting examples, hardware, software, firmware, special purpose circuits or logic, general purpose hardware or controller or other computing devices, or some combination thereof.

The present disclosure also provides at least one computer program product tangibly stored on a non-transitory computer readable storage medium. The computer program product includes computer-executable instructions, such as those included in program modules, being executed in a device on a target real or virtual processor, to carry out the methods 400 and/or 500 as described above with reference to FIG. 4 and/or FIG. 5. Generally, program modules include routines, programs, libraries, objects, classes, components, data structures, or the like that perform particular tasks or implement particular abstract data types. The functionality of the program modules may be combined or split between program modules as desired in various embodiments. Machine-executable instructions for program modules may be executed within a local or distributed device. In a distributed device, program modules may be located in both local and remote storage media.

Program code for carrying out methods of the present disclosure may be written in any combination of one or more programming languages. These program codes may be provided to a processor or controller of a general purpose computer, special purpose computer, or other programmable data processing apparatus, such that the program codes, when executed by the processor or controller, cause the functions/operations specified in the flowcharts and/or block diagrams to be implemented. The program code may execute entirely on a machine, partly on the machine, as a stand-alone software package, partly on the machine and partly on a remote machine or entirely on the remote machine or server.

In the context of the present disclosure, the computer program codes or related data may be carried by any suitable carrier to enable the device, apparatus or processor to perform various processes and operations as described above. Examples of the carrier include a signal, computer readable medium, and the like.

The computer readable medium may be a computer readable signal medium or a computer readable storage medium. A computer readable medium may include but not limited to an electronic, magnetic, optical, electromagnetic, infrared, or semiconductor system, apparatus, or device, or any suitable combination of the foregoing. More specific examples of the computer readable storage medium would include an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous. Likewise, while Several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in languages specific to structural features and/or methodological acts, it is to be understood that the present disclosure defined in the appended claims is not necessarily limited to the specific features or acts described above. Rather, the specific features and acts described above are disclosed as example forms of implementing the claims.

1. An apparatus comprising:
at least one processor; and
at least one non-transitory memory storing instructions that, when executed with the at least one processor, cause the apparatus to:
forward, during a first period, first sounding reference signal data received from a terminal device to a further apparatus;
receive, from the further apparatus, compression information for compressing sounding reference signal data, the compression information being determined based on the first sounding reference signal data;
compress, during a second period, second sounding reference signal data received from the terminal device based on the compression information; and
transmit, during the second period, the compressed second sounding reference signal data to the further apparatus.

2. The apparatus of claim 1, wherein the instructions, when executed with the at least one processor, cause the apparatus to:
in accordance with a determination that the compression information comprises spatial domain compression information, compress spatial dimensions of the second sounding reference signal data based on the spatial domain compression information; and
in accordance with a determination that the compression information comprises frequency domain compression information, compress frequency units of the second sounding reference signal data based on the frequency domain compression information.

3. The apparatus of claim 1, wherein the apparatus is a radio frequency unit of a network device and the further apparatus is a baseband unit of the network device.

4. The apparatus of claim 3, wherein the instructions, when executed with the at least one processor, cause the apparatus to:
forward, via at least one fronthaul link between the radio frequency unit and the baseband unit, the first sounding reference signal data from the radio frequency unit to the baseband unit during the first period;
receive, via the at least one fronthaul link, the compression information from the baseband unit; and
transmit, via the at least one fronthaul link, the compressed second sounding reference signal data from the radio frequency unit to the baseband unit during the second period.

5. An apparatus comprising:
at least one processor; and
at least one non-transitory memory storing instructions that, when executed with the at least one processor, cause the apparatus to:
receive, during a first period, first sounding reference signal data from a further apparatus;
determine, based on the first sounding reference signal data, compression information for compressing sounding reference signal data;
transmit the compression information to the further apparatus; and
receive, during a second period, second sounding reference signal data compressed based on the compression information from the further apparatus.

6. The apparatus of claim 5, wherein the instructions, when executed with the at least one processor, cause the apparatus to:
perform a channel estimation based on the first sounding reference signal data.

7. The apparatus of claim 5, wherein the instructions, when executed with the at least one processor, cause the apparatus to:
decompress the received second sounding reference signal data based on the compression information; and
perform a channel estimation based on the decompressed second sounding reference signal data.

8. The apparatus of claim 5, wherein the compression information comprises spatial domain compression information, and wherein the instructions, when executed with the at least one processor, cause the apparatus to:
receive the second sounding reference signal data from the further apparatus during the second period, spatial dimensions of the second sounding reference signal data being compressed based on the spatial domain compression information.

9. The apparatus of claim 5, wherein the compression information comprises frequency domain compression information, and wherein the instructions, when executed with the at least one processor, cause the apparatus to:
receive the second sounding reference signal data from the further apparatus during the second period, frequency units of the second sounding reference signal data being compressed based on the frequency domain compression information.

10. The apparatus of claim 5, wherein the apparatus is a baseband unit of a network device and the further apparatus is a radio frequency unit of the network device.

11. The apparatus of claim 10, wherein the instructions, when executed with the at least one processor, cause the apparatus to:
receive, via at least one fronthaul link between the radio frequency unit and the baseband unit, the first sounding reference signal data from the radio frequency unit during the first period;
transmit, via the at least one fronthaul link, the compression information from the baseband unit to the radio frequency unit; and
receive, via the at least one fronthaul link, the second sounding reference signal data from the radio frequency unit during the second period.

12. A method comprising:
forwarding, at an apparatus and during a first period, first sounding reference signal data received from a terminal device to a further apparatus;
receiving, from the further apparatus, compression information for compressing sounding reference signal data, the compression information being determined based on the first sounding reference signal data;
compressing, during a second period, second sounding reference signal data received from the terminal device based on the compression information; and
transmitting, during the second period, the compressed second sounding reference signal data to the further apparatus.

13. The method of claim 12, wherein compressing the second sounding reference signal data comprises:
in accordance with a determination that the compression information comprises spatial domain compression information, compressing spatial dimensions of the second sounding reference signal data based on the spatial domain compression information; and
in accordance with a determination that the compression information comprises frequency domain compression information, compressing frequency units of the second sounding reference signal data based on the frequency domain compression information.

14. The method of claim 12, wherein the apparatus is a radio frequency unit of a network device and the further apparatus is a baseband unit of the network device.

15. The method of claim 14,
wherein forwarding the first sounding reference signal data comprises:
forwarding, via at least one fronthaul link between the radio frequency unit and the baseband unit, the first sounding reference signal data from the radio frequency unit to the baseband unit during the first period;
wherein receiving the compression information comprises:
receiving, via the at least one fronthaul link, the compression information from the baseband unit; and
wherein transmitting the compressed second sounding reference signal data comprises:
transmitting, via the at least one fronthaul link, the compressed second sounding reference signal data from the radio frequency unit to the baseband unit during the second period.

16-26. (canceled)

27. A non-transitory computer readable medium comprising program instructions stored thereon for performing the method as claimed in claim 12.
